(19) United States
(12) Patent Application Publication
(10) Pub. No.: US 2023/0215776 A1
(43) Pub. Date: Jul. 6, 2023

(54) SEMICONDUCTOR DEVICE

(71) Applicant: Mitsubishi Electric Corporation, Tokyo (JP)

(72) Inventor: Kenji SAITO, Tokyo (JP)

(73) Assignee: Mitsubishi Electric Corporation, Tokyo (JP)

(21) Appl. No.: 18/054,099

(22) Filed: Nov. 9, 2022

(30) Foreign Application Priority Data
Jan. 5, 2022 (JP) 2022-000572

(51) Int. Cl. H01L 23/42; H01L 23/053; H01L 23/14; H01L 23/492; H01L 23/40

(52) U.S. Cl. CPC H01L 23/42; H01L 23/053; H01L 23/142; H01L 23/492; H01L 23/4006; H01L 24/32; H01L 2224/32245

(57) ABSTRACT

A semiconductor device includes: an insulating substrate; a semiconductor chip; a base plate; a first heat dissipating material; and a case. The semiconductor chip and a sealing material for sealing the semiconductor chip are housed in the case. The insulating substrate includes an insulating layer and a conductor pattern provided on an upper surface of the insulating layer. The semiconductor chip is joined onto the conductor pattern by a joining material. A lower surface of the insulating substrate and an upper surface of the base plate are in contact with each other with interposition of the first heat dissipating material. The insulating substrate and the base plate are not fixed to each other.

### BACKGROUND OF THE INVENTION

### Field of the Invention

The present disclosure relates to a semiconductor device.

### Description of the Background Art

Japanese Patent Application Laid-Open No. 2012-028561 discloses a semiconductor device including: an insulating substrate having one surface mounted with a semiconductor element; and a heat sink having a plate shape, the heat sink having one surface joined in a heat transferring manner to another surface of the insulating substrate through a buffer material.

In the conventional techniques, there has been a problem that a semiconductor device is deformed due to a temperature rise, pumping-out being a phenomenon in which a heat dissipating material is pushed out due to the deformation occurs, the pushed out heat dissipating material does not return to its original state during cooling to form a gap, and heat dissipation is deteriorated.

### SUMMARY

An object of the present disclosure is to provide a semiconductor device capable of suppressing pumping out of a heat dissipating material and thereby suppressing decrease in heat dissipation.

A semiconductor device of the present disclosure includes: an insulating substrate; a semiconductor chip; a base plate; a first heat dissipating material; and a case. The semiconductor chip and a sealing material for sealing the semiconductor chip are housed in the case. The insulating substrate includes an insulating layer and a conductor pattern provided on an upper surface of the insulating layer. The semiconductor chip is joined onto the conductor pattern by a joining material. A lower surface of the insulating substrate and an upper surface of the base plate are in contact with each other with interposition of the first heat dissipating material. The insulating substrate and the base plate are not fixed to each other.

With the present disclosure, there is provided a semiconductor device capable of suppressing pumping out of a heat dissipating material, thereby suppressing decrease in heat dissipation.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a cross-sectional view of a semiconductor device of a first preferred embodiment;

FIG. 2 is a cross-sectional view of a semiconductor device of a comparative example;

FIG. 3 is a cross-sectional view of a semiconductor device of a comparative example;

FIG. 4 is a cross-sectional view of a semiconductor device of a second preferred embodiment;

FIG. 5 is a cross-sectional view of a semiconductor device of a third preferred embodiment; and

FIG. 6 is a view showing a manufacturing process of the semiconductor device of the third preferred embodiment.

### DESCRIPTION OF THE PREFERRED EMBODIMENTS

### A. First Preferred Embodiment

### A-1. Configuration

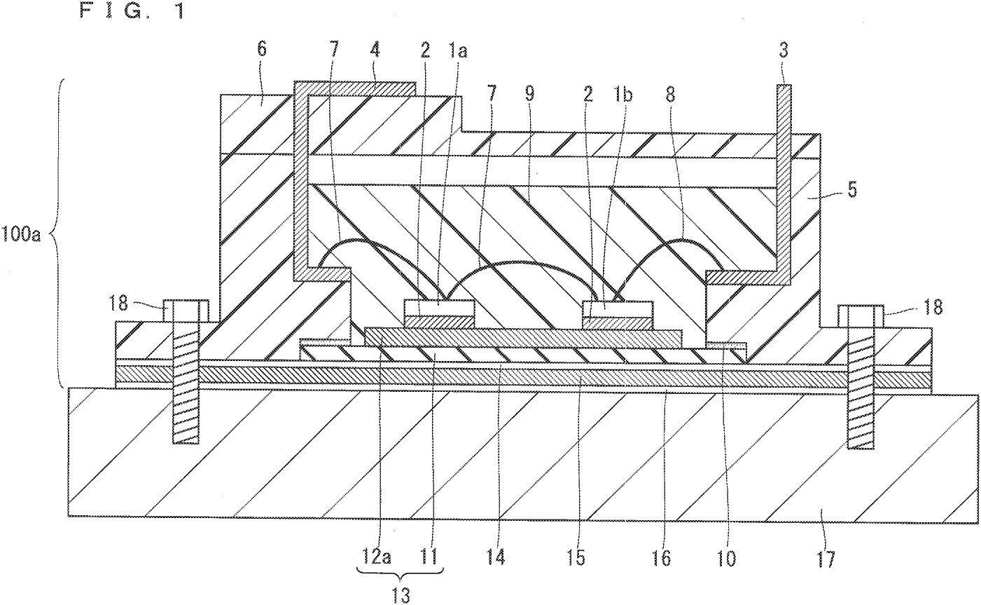

FIG. 1 is a diagram showing a semiconductor device 100a according to a first preferred embodiment.

The semiconductor device 100a is a power semiconductor device.

The semiconductor device 100a includes a semiconductor chip 1a, a semiconductor chip 1b, solder 2, a signal terminal 3, a main terminal 4, a case 5, a lid 6, a wire 7, a wire 8, a sealing material 9, an adhesive 10, an insulating substrate 13, a heat dissipating material 14, and a base plate 15.

The insulating substrate 13 includes an insulating layer 11 and a conductor pattern 12a provided on the upper surface of the insulating layer 11.

A material of the insulating layer 11 is, for example, ceramic or resin.

The conductor pattern 12a is a pattern formed of, for example, copper, a copper alloy, aluminum, or an aluminum alloy.

The semiconductor chip 1a and the semiconductor chip 1b are joined onto the conductor pattern 12a by the solder 2.

The semiconductor chip 1a and the semiconductor chip 1b are disposed in the case 5 and sealed by the sealing material 9.

The case 5 is, for example, a resin case. The material of the case 5 is, for example, poly phenylene sulfide resin (PPS).

The sealing material 9 is, for example, a gel. The gel is, for example, a silicone gel.

The case 5 is attached with the lid 6.

The case 5 is bonded to the insulating substrate 13 with the adhesive 10.

The case 5 is attached with the signal terminal 3 and the main terminal 4. The main terminal 4 is a terminal for power. Although only one main terminal 4 is shown in the cross section shown in FIG. 1, a plurality of main terminals 4 are attached to the case 5.

The semiconductor chip 1a is, for example, a diode, and the semiconductor chip 1b is, for example, an insulated gate bipolar transistor (IGBT). The semiconductor chip 1b may be a metal oxide semiconductor field effect transistor (MOSFET). The semiconductor device 100a may include a reverse-conducting IGBT (RC-IGBT), instead of including the semiconductor chip 1a being a diode and the semiconductor chip 1b being an IGBT. Each of the semiconductor chip 1a and the semiconductor chip 1b is, for example, a semiconductor chip using any one of a Si semiconductor, a SiC semiconductor, and a GaN semiconductor.

The main terminal 4 shown in FIG. 1 is connected to the upper surfaces of the semiconductor chip 1a and the semiconductor chip 1b by the wire 7. A main terminal 4 different from the main terminal 4 shown in FIG. 1 is connected to the conductor pattern 12a in a cross section different from that in FIG. 1, for example. The signal terminal 3 is connected to the semiconductor chip 1b. The semiconductor chip 1b controls a current flowing between the main terminals 4 according to a signal input from the outside of the semiconductor device 100a through the signal terminal 3.

The lower surface of the insulating layer 11, that is, the lower surface of the insulating substrate 13 is in contact with the base plate 15 with interposition of the heat dissipating material 14. The base plate 15 is a metal plate. The base plate 15 is a plate of, for example, copper, a copper alloy, aluminum, or an aluminum alloy. The heat dissipating material 14 is, for example, grease or a heat dissipating sheet.

For example, the entire lower surface of the insulating substrate 13 is in contact with the base plate 15 with interposition of the heat dissipating material 14.

When the heat dissipating material 14 is a heat dissipating sheet, the heat dissipating sheet is not bonded to at least one of the insulating substrate 13 and the base plate 15.

In FIG. 1, the semiconductor device 100a is attached to a radiator 17 by screws 18. The lower surface of the base plate 15 is in contact with the radiator 17 with interposition of the heat dissipating material 16. The heat generated by the semiconductor chip 1a or the semiconductor chip 1b is transferred to the radiator 17 through, for example, the solder 2, the conductor pattern 12a, the insulating layer 11, the heat dissipating material 14, the base plate 15, and the heat dissipating material 16. The material of the radiator 17 is, for example, copper, a copper alloy, aluminum, or an aluminum alloy. The radiator 17 may be provided with fins. The semiconductor device of the present preferred embodiment may include the heat dissipating material 16 and the radiator 17 in addition to the semiconductor device 100a.

The heat dissipating material 16 is, for example, grease or a heat dissipating sheet. The heat dissipating material 16 may have conductivity. When the heat dissipating material 16 has conductivity, the potential of the base plate 15 can be made equal to that of the radiator 17, and discharge between the base plate 15 and the radiator 17 can be suppressed.

Since the semiconductor device 100a is attached to the radiator 17 by the screws 18, the base plate 15 is sandwiched and supported from above and below by the case 5 and the radiator 17.

The insulating substrate 13 and the base plate 15 are not fixed to each other. That is, when the base plate 15 is thermally expanded during the operation of the semiconductor device 100a, the relative position in the in-plane direction between the lower surface of the insulating substrate 13 and the upper surface of the base plate 15 can be changed. The base plate 15 is in contact with the lower surface of the case 5 with interposition of the heat dissipating material 14. The base plate 15 is not fixed to the case 5. That is, when the base plate 15 is thermally expanded during the operation of the semiconductor device 100a, the relative position in the in-plane direction between the lower surface of the case 5 and the upper surface of the base plate 15 can be changed.

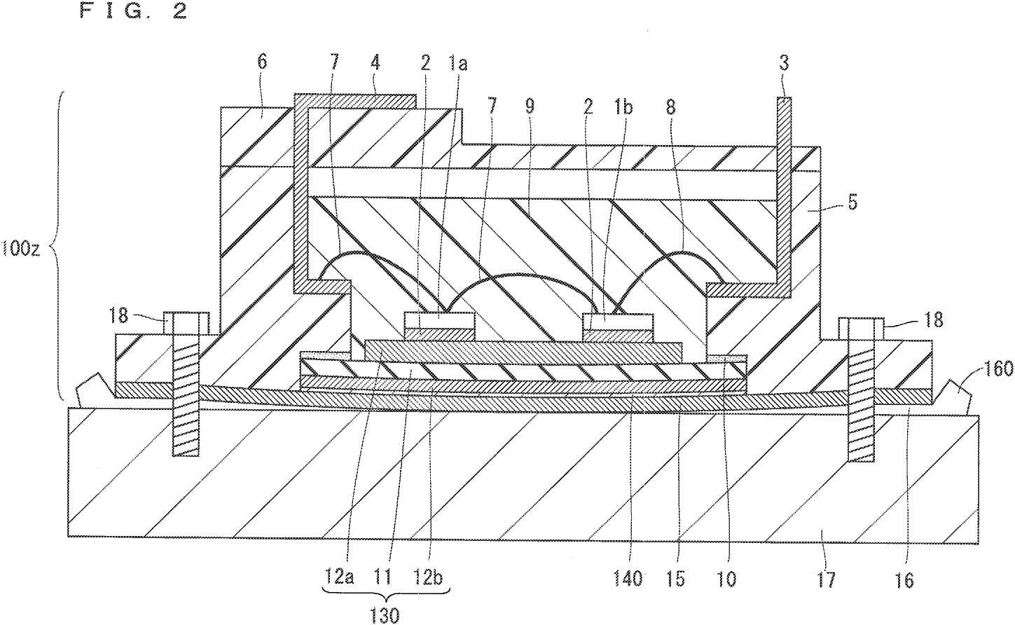

FIG. 2 is a diagram showing a semiconductor device 100z of a comparative example. Compared with the semiconductor device 100a, the semiconductor device 100z includes an insulating substrate 130 instead of the insulating substrate 13. The insulating substrate 130 includes a conductor pattern 12a provided on the upper surface of the insulating layer 11 and a conductor pattern 12b provided on the lower surface of the insulating layer 11. In addition, in the semiconductor device 100z, the conductor pattern 12b of the insulating substrate 130 and the base plate 15 are fixed by solder 140. The semiconductor device 100z is similar to the semiconductor device 100a except for these points.

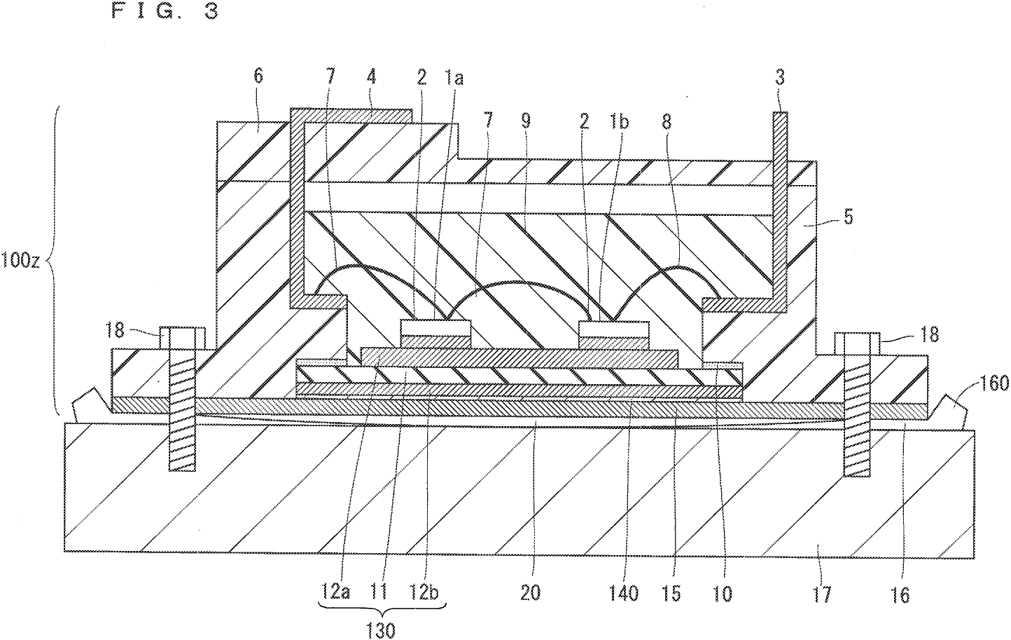

In the semiconductor device 100z, the insulating substrate 130 and the base plate 15 are fixed to each other. The linear expansion coefficient of the base plate 15 is larger than the linear expansion coefficient of the insulating layer 11. Therefore, when the temperature of the semiconductor device 100z rises, the base plate 15 deforms and protrudes toward the radiator 17 due to the difference in the expansion coefficient between the insulating substrate 13 and the base plate 15. FIG. 2 shows the semiconductor device 100z in this situation. The deformation of the base plate 15 causes pumping out of the heat dissipating material 16 between the semiconductor device 100z and the radiator 17. When the temperature of the semiconductor device 100z drops, in the heat dissipating material 16, the portion 160 pushed out due to the deformation of the base plate 15 does not return to the original state, and a gap 20 is formed between the semiconductor device 100z and the radiator 17, which hinders heat radiation (see FIG. 3).

On the other hand, in the semiconductor device 100a of the present preferred embodiment, since the insulating substrate 13 and the base plate 15 are not fixed to each other, even when the temperature of the semiconductor device 100a rises, the base plate 15 does not protrude or is less likely to protrude toward the radiator 17. Therefore, the influence of the difference between the expansion coefficient of the insulating substrate 13 and the expansion coefficient of the base plate 15 is suppressed, and the pumping out of the heat dissipating material 16 is suppressed. Accordingly, decrease in heat dissipation can be suppressed.

The semiconductor device 100a may include an insulating substrate 130 instead of the insulating substrate 13. In this case, the lower surface of the insulating substrate 130, that is, the lower surface of the conductor pattern 12b provided on the lower surface of the insulating layer 11 is in contact with the base plate 15 with interposition of the heat dissipating material 14. Also in this case, since the insulating substrate 130 and the base plate 15 are not fixed to each other, even when the temperature of the semiconductor device 100a rises, the base plate 15 does not protrude or is less likely to protrude toward the radiator 17. Therefore, the influence of the difference between the expansion coefficient of the insulating substrate 130 and the expansion coefficient of the base plate 15 is suppressed, and the pumping out of the heat dissipating material 16 is suppressed. In order to prevent the insulating substrate 130 from protruding downward due to the difference in the linear expansion coefficient between the conductor pattern 12b and the insulating layer 11 and causing pumping out of the heat dissipating material 14 when the temperature of the semiconductor device 100a rises, the thickness of the conductor pattern 12b is preferably equal to or less than the thickness of the conductor pattern 12a.

Since a semiconductor chip using a wide band gap semiconductor operates at a higher temperature than a semiconductor chip using silicon, when at least one of the semiconductor chip 1a and the semiconductor chip 1b is a semiconductor chip using the wide band gap semiconductor, pumping out is more likely to occur in the semiconductor device 100z of the comparative example. In the semiconductor device 100a of the present preferred embodiment, since the insulating substrate 13 or the insulating substrate 130 and the base plate 15 are not fixed to each other, even when at least one of the semiconductor chip 1a and the semiconductor chip 1b is a semiconductor chip using a wide band gap semiconductor, pumping out can be suppressed, so that decrease in heat dissipation can be suppressed. Here, the wide band gap semiconductor is a semiconductor having a larger band gap than a silicon semiconductor, and is, for example, a SiC semiconductor or a GaN semiconductor.

### B. Second Preferred Embodiment

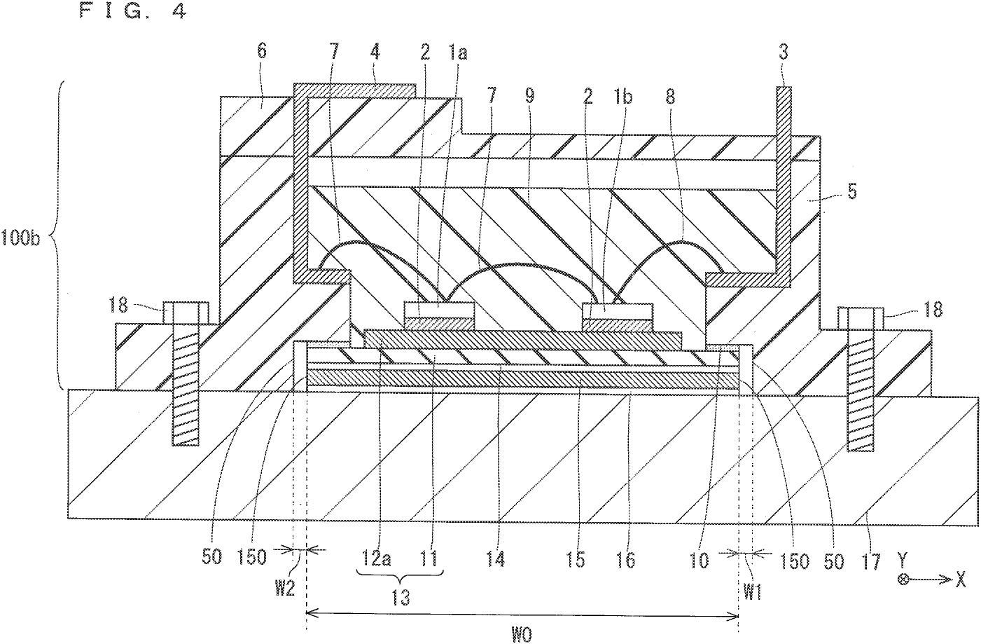

FIG. 4 is a diagram showing a semiconductor device 100b according to a second preferred embodiment.

The semiconductor device 100b is different from the semiconductor device 100a of the first preferred embodiment in that the base plate 15 is surrounded by the case 5 in plan view, and the inner side surface 50 of the case 5 faces the side surface 150 of the base plate 15. The semiconductor device 100b is similar to the semiconductor device 100a of the first preferred embodiment in other points.

The base plate 15 is smaller than the case 5 in plan view. There is an interval in the in-plane direction between the inner side surface 50 of the case 5 and the side surface 150 of the base plate 15. Since there is an interval in the in-plane direction between the inner side surface 50 of the case 5 and the side surface 150 of the base plate 15, even when the temperature of the base plate 15 rises and expands during the operation of the semiconductor device 100b, the contact between the base plate 15 and the case 5 can be avoided, or a force applied to the case 5 and the base plate 15 when the base plate 15 and the case 5 come into contact with each other can be suppressed.

Assuming that the temperature rise range of the base plate 15 is 125 K, when the base plate 15 is a copper plate, since the linear expansion coefficient of copper is 16.8 × 10⁻⁶/K, the base plate 15 expands by 100% × 16.8 × 10⁻⁶/K × 125 K = 0.21%. There has only to be an interval of 0.13% or more of the width W0 in the X direction of the base plate 15, with respect to the direction in a plane, in the X direction (see FIG. 4) being one direction in the plane and in the direction opposite to the X direction, between the inner side surface 50 of the case 5 and the side surface 150 of the base plate 15, that is, the magnitude of the interval W1 and the interval W2 has only to be 0.13% or more of the width W0. The same applies to the Y direction in the plane orthogonal to the X direction. That is, there has only to be an interval of 0.13% or more of the width in the Y direction of the base plate 15, with respect to the direction in the plane, in the Y direction in the plane orthogonal to the X direction and the direction opposite to the Y direction, between the inner side surface 50 of the case 5 and the side surface 150 of the base plate 15. With this configuration, even when the temperature of the base plate 15 rises by 125 K, the contact between the base plate 15 and the case 5 can be avoided, or a force applied to the case 5 and the base plate 15 when the base plate 15 and the case 5 come into contact with each other can be suppressed.

The size of a general semiconductor module is 150 mm or less. Assuming that the size of the base plate 15 in plan view is 150 mm or less and the temperature rise width of the base plate 15 is 125 K, when the base plate 15 is a copper plate, since the linear expansion coefficient of copper is 16.8 × 10⁻⁶/K, the base plate 15 expands by 16.8 × 10⁻⁶/K × 125 K × 150 mm = 0.315 mm due to the temperature rise. Between the inner side surface 50 of the case 5 and the side surface 150 of the base plate 15, there has only to be an interval of 0.2 mm or more with respect to the in-plane direction, in the X direction being one direction in the plane and the direction opposite to the X direction, and there has only to be an interval of 0.2 mm or more with respect to the in-plane direction, in the Y direction in the plane orthogonal to the X direction and the direction opposite to the Y direction. With this configuration, even when the temperature of the base plate 15 rises by 125 K, the contact between the base plate 15 and the case 5 can be avoided, or a force applied to the case 5 and the base plate 15 when the base plate 15 and the case 5 come into contact with each other can be suppressed.

The semiconductor device of the present preferred embodiment may include the heat dissipating material 16 and the radiator 17 in addition to the semiconductor device 100b.

### C. Third Preferred Embodiment

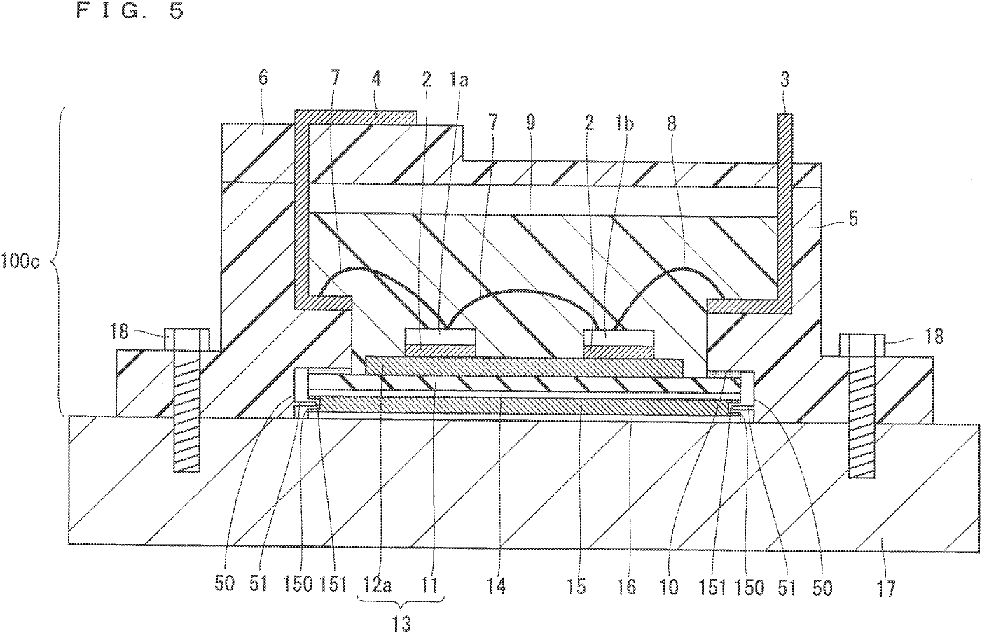

FIG. 5 is a diagram showing a semiconductor device 100c according to a third preferred embodiment. In the semiconductor device 100c, a groove 151 extending along the outer periphery of the base plate 15 is provided on the side surface 150 of the base plate 15. The groove 151 may be provided on the entire outer periphery in the side surface 150 of the base plate 15 or may be provided on a part of the outer periphery. The case 5 includes a protrusion 51. The protrusion 51 is provided in a portion facing the side surface 150 of the base plate 15 in the inner side surface 50 of the case 5. The protrusion 51 at least partially enters the groove 151. The semiconductor device 100c is similar to the semiconductor device 100b of the second preferred embodiment except for these points.

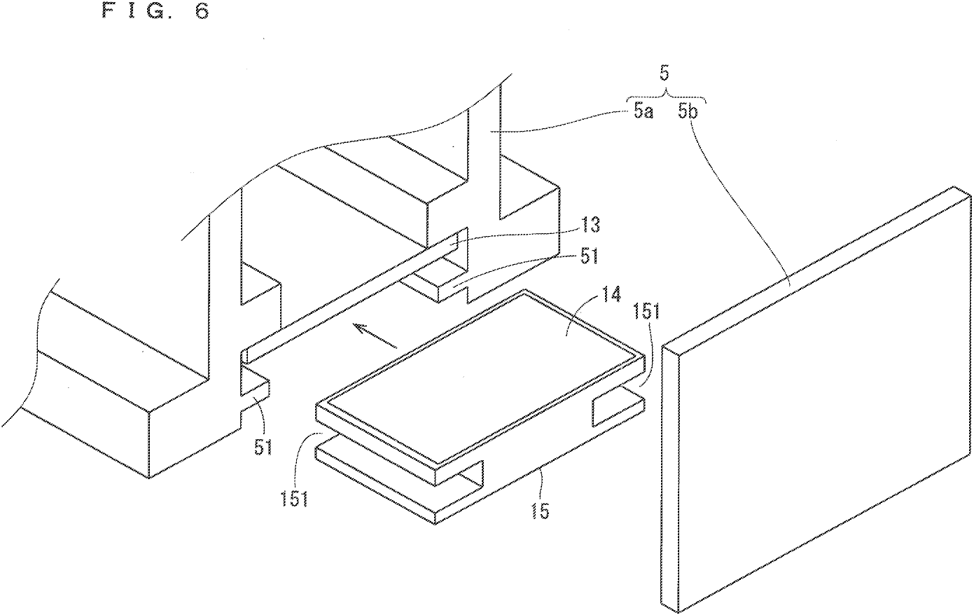

As shown in FIG. 6, the case 5 includes, for example, a main body 5a and a side surface lid 5b. When the semiconductor device 100c is manufactured, for example, the base plate 15 slides from a side surface as indicated by an arrow in FIG. 6 and is attached to the main body 5a of the case 5, and then the side surface lid 5b is attached to the side surface of the main body 5a with a screw or an adhesive. For example, as shown in FIG. 6, after the insulating substrate 13 is bonded to the case 5 with the adhesive 10, the base plate 15 is attached to the main body 5a of the case 5 with the heat dissipating material 14 disposed on the upper surface.

In order to prevent the base plate 15 from coming into contact with the protrusion 51 when the base plate 15 expands, it is preferable that the tip of the protrusion 51 does not reach the depth of the groove 151, and it is preferable that there is a gap between the tip of the protrusion 51 and the depth of the groove 151 in the in-plane direction.

As shown in FIG. 5, the protrusion 51 and the groove 151 are not fitted to each other, and there is a gap between the protrusion 51 and the surface of the groove 151. The protrusion 51 and the groove 151 may be fitted to each other. In this case, it is preferable that the degree of fitting between the protrusion 51 and the groove 151 is such that there is no problem in sliding the base plate 15 from the side surface as shown in FIG. 6 to attach the base plate 15 to the main body 5a.

Since the protrusion 51 at least partially enters the groove 151, the base plate 15 and the case 5 are integrated. Since the base plate 15 and the case 5 are integrated, the base plate 15, the insulating substrate 13, the semiconductor chip 1a, and the semiconductor chip 1b can be prevented from falling off from the case 5. Therefore, even when the semiconductor device 100c includes a plurality of insulating substrates 13, the semiconductor device 100c can be easily handled.

The semiconductor device of the present preferred embodiment may include the heat dissipating material 16 and the radiator 17 in addition to the semiconductor device 100c.

It should be noted that each preferred embodiment can be freely combined, and each preferred embodiment can be appropriately modified or omitted.

While the disclosure has been shown and described in detail, the foregoing description is in all aspects illustrative and not restrictive. It is therefore understood that numerous modifications and variations can be devised.

What is claimed is:

1. A semiconductor device comprising:
an insulating substrate;
a semiconductor chip;
a base plate;
a first heat dissipating material; and
a case,
wherein the semiconductor chip and a sealing material for sealing the semiconductor chip are housed in the case,
wherein the insulating substrate includes an insulating layer and a conductor pattern provided on an upper surface of the insulating layer,
wherein the semiconductor chip is joined onto the conductor pattern by a joining material,
wherein a lower surface of the insulating substrate and an upper surface of the base plate are in contact with each other with interposition of the first heat dissipating material, and
wherein the insulating substrate and the base plate are not fixed to each other.

2. The semiconductor device according to claim 1, wherein the lower surface of the insulating substrate is a lower surface of the insulating layer.

3. The semiconductor device according to claim 1,
wherein an inner side surface of the case faces a side surface of the base plate, and
wherein there is an interval in an in-plane direction between the inner side surface of the case and the side surface of the base plate.

4. The semiconductor device according to claim 3, wherein between the inner side surface of the case and the side surface of the base plate, on one direction side in a plane and on a direction side opposite to the one direction, there is an interval of 0.2 mm or more in an in-plane direction.

5. The semiconductor device according to claim 4, wherein between the inner side surface of the case and the side surface of the base plate, on another direction side in a plane orthogonal to the one direction and on a direction side opposite to the another direction, there is an interval of 0.2 mm or more in an in-plane direction.

6. The semiconductor device according to claim 3, wherein between the inner side surface of the case and the side surface of the base plate, on one direction side in a plane and on a direction side opposite to the one direction, there is an interval of 0.13% or more of a width in the one direction of the base plate in an in-plane direction.

7. The semiconductor device according to claim 6, wherein between the inner side surface of the case and the side surface of the base plate, on another direction side in a plane orthogonal to the one direction and on a direction side opposite to the another direction, there is an interval of 0.13% or more of a width in the another direction of the base plate in an in-plane direction.

8. The semiconductor device according to claim 3,
wherein a groove extending along an outer periphery of the base plate is provided on the side surface of the base plate,
wherein a protrusion is provided in a portion facing the side surface of the base plate on the inner side surface of the case, and
wherein the protrusion at least partially enters the groove.

9. The semiconductor device according to claim 1, wherein the sealing material is gel.

10. The semiconductor device according to claim 1, wherein the first heat dissipating material is grease or a heat dissipating sheet.

11. The semiconductor device according to claim 1,
further comprising a second heat dissipating material and a radiator,
wherein a lower surface of the base plate is in contact with the radiator with interposition of the second heat dissipating material.

12. The semiconductor device according to claim 11, wherein the second heat dissipating material is grease or a heat dissipating sheet.

13. The semiconductor device according to claim 11, wherein the second heat dissipating material has conductivity.
